(19) United States
(12) Patent Application Publication
(10) Pub. No.: US 2008/0036083 A1
(43) Pub. Date: Feb. 14, 2008

(54) Semiconductor device and method of manufacturing the same

(75) Inventors: Yuko Sawada, Tokyo (JP); Shinji Baba, Tokyo (JP); Takahiro Sugimura, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/882,662

(22) Filed: Aug. 3, 2007

(30) Foreign Application Priority Data
Aug. 9, 2006 (JP) 2006-217000

(51) Int. Cl. H01L 23/48; H01L 21/00

(52) U.S. Cl. 257/737; 257/778; 438/108; 257/E23.01; 257/E21.001

(57) ABSTRACT

The semiconductor device which can prevent destruction of a low dielectric constant film and a bump's destruction which consists of lead free solder both is obtained.

A semiconductor package which has a semiconductor chip including a low dielectric constant film and a bump which consists of lead free solder, a wiring substrate by which flip chip junction of the semiconductor package was done via the bump, and under-filling resin, with which a gap between the semiconductor package and the wiring substrate is filled up, are provided. As for under-filling resin, the glass transition temperature is equal to or more than 125° C., the coefficient of thermal expansion in 125° C. is less than 40 ppm/° C., and the elastic modulus in 25° C. is less than 9 GPa.

### CROSS-REFERENCE TO RELATED APPLICATION

The present application claims priority from Japanese patent application No. 2006-217000 filed on Aug. 9, 2006, the content of which is hereby incorporated by reference into this application.

### 1. FIELD OF THE INVENTION

The present invention relates to the semiconductor device provided with a semiconductor package which has a semiconductor chip including a low dielectric constant film and a bump which consists of lead free solder, a wiring substrate by which flip chip junction of the semiconductor package was done via the bump, and under-filling resin with which a gap between the semiconductor package and the wiring substrate is filled up, and its manufacturing method.

### 2. DESCRIPTION OF THE BACKGROUND ART

The semiconductor device which makes flip chip connection of the semiconductor chip via the bump at the wiring substrate is used. In this semiconductor device, in order to protect a bump, the gap between a semiconductor chip and a wiring substrate is filled up with under-filling resin. A semiconductor chip comes to include a low dielectric constant film (Low-k film) as an interlayer insulation film, and a bump has come to comprise lead free solder in recent years.

[Patent Reference 1] Japanese Unexamined Patent Publication No. Hei 8-92352

[Patent Reference 2] Japanese Unexamined Patent Publication No. 2004-307647

[Patent Reference 3] Japanese Unexamined Patent Publication No.

[Patent Reference 4] Japanese Unexamined Patent Publication No. Hei 11-87414

[Patent Reference 5] Japanese Unexamined Patent Publication No. Hei 11-163203

[Patent Reference 6] Japanese Unexamined Patent Publication No. 2002-353361

[Patent Reference 7] Japanese Unexamined Patent Publication No. 2003-51573

[Patent Reference 8] Japanese Unexamined Patent Publication No. 2005-251784

### SUMMARY OF THE INVENTION

As under-filling resin, those of as high the elastic modulus as more than 11 GPa in minimum −55° C. of the general operation-ensuring-temperature range (−55° C. to 125° C.) and glass transition temperature Tg higher than maximum 125° C. of the operation-ensuring-temperature range, for example, of 130° C. to 140° C. were used (for example, refer to Patent References 1-3). Here, under-filling resin becomes hard below Tg, and internal stress will become large as it cools. Therefore, when the above under-filling resin whose elastic modulus is high at the low temperature side was used, there was a problem that internal stress concentrated to a semiconductor chip corner part etc. at the time of low temperature, and peeling occurred in a low dielectric constant film with low durability.

On the other hand, such a problem will not arise when using under-filling resin whose elastic modulus is low at the low temperature side. As such under-filling resin, those having characteristics that elastic modulus is as low as below 9 GPa in a low temperature region, and that Tg is lower than maximum 125° C. of the operation-ensuring-temperature range was evaluated. Here, in the case of the under-filling resin which uses epoxy system resin and bismaleide triazine system resin as a base material, the coefficient of thermal expansion less than Tg is around 20˜40 ppm/° C., but when Tg is exceeded, a coefficient of thermal expansion will become very large with around 90 ppm/° C. Therefore, since the cubical expansion at the time of high temperature was large when the above conventional under-filling resin whose elastic modulus is low at the low temperature side was used, the problem arose that the bump which consists of lead free solder with a low creep limit could not do relief of stress and was destroyed.

Thus, in resin with high Tg and a small coefficient of thermal expansion in a pyrosphere, there is a problem of an elastic modulus being high in a low temperature region, and of causing peeling of the low dielectric constant film by big stress concentration. In resin with an elastic modulus low in a low temperature region, Tg is lower than the maximum of the operation-ensuring-temperature range, and since a coefficient of thermal expansion becomes extremely large in the temperature range exceeding Tg, there is a problem of causing a lead free solder bump's destruction. Since under-filling resin with an elastic modulus low in a low temperature region and small cubical expansion in a pyrosphere was not used, both of destruction of a low dielectric constant film and the bump's destruction which consists of lead free solder were not able to be prevented.

The semiconductor package which attaches the semiconductor chip to the porosity elastomer and to which the porosity elastomer is exposed from the package side surface is proposed (for example, refer to Patent References 4-6). According to this, when the semiconductor package in the state where it absorbed moisture is reflowed, the steam generated inside the package at the time of reflow can be emitted outside through a porosity elastomer. However, in the conventional semiconductor device, since under-filling resin had covered the package side surface, the porosity elastomer exposed from the package side surface was covered with under-filling resin. For this reason, there was a problem that steam could not be emitted outside through a porosity elastomer.

Since the release agent is included in mold resin, adhesion of mold resin with under-filling resin is bad. Therefore, when the semiconductor package whose mold resin exposed to the ball face side was used, there was a problem that peeling occurs in the interface of mold resin and under-filling resin, this peeling spread and destruction of internal wiring and the short-circuit of solder balls occurred.

Further, for heat radiation, the upper surface of the semiconductor element mounted on wiring substrate sticks to cases, such as car navigation and a personal computer, or is fixed to the cases via heat conduction material. And when semiconductor elements having different heights, such as a microcomputer and DRAM, were mounted on a wiring substrate, conventionally, the thermally conductive insulating member was formed on each semiconductor element to make the same height, and adhered to the flat case (for example, refer to Patent References 7 and 8). However, since thermal conductivity of the insulating member was low compared with metal, the insulating member had the problem that heat radiation property is lowered.

The present invention is made in order to solve the above problems. The first purpose of the present invention is to obtain the semiconductor device which can prevent destruction of a low dielectric constant film and a bump's destruction which consists of lead free solder both.

The second purpose of the present invention is to obtain the semiconductor device which can prevent hampering emission of the steam which is let pass to the elastomer with under-filling resin.

The third purpose of the present invention is to obtain the semiconductor device which can prevent peeling of the interface of the mold resin exposed to the ball face side of a semiconductor package and under-filling resin spreading, and destruction of internal wiring and the short-circuit of solder balls occurring.

The fourth purpose of the present invention is to obtain the semiconductor device which can secure the heat radiation property from each semiconductor element to a case, even when the semiconductor element from which height differs is mounted on a wiring substrate.

A semiconductor device concerning claim 1 of the present invention comprises a semiconductor package which has a semiconductor chip including a low dielectric constant film and a bump which includes lead free solder, a wiring substrate over which flip chip junction of the semiconductor package was done via the bump, and under-filling resin with which is filled up between the semiconductor package and the wiring substrate, wherein as for the under-filling resin, glass transition temperature is equal to or more than 125° C., coefficient of thermal expansion in 125° C. is less than 40 ppm/° C., and elastic modulus in 25° C. is less than 9 GPa.

A semiconductor device concerning claim 3 of the present invention comprises a semiconductor package which has a semiconductor chip and a porosity elastomer to which the semiconductor chip is attached and which is exposed from a package side surface, a wiring substrate to which the semiconductor package is joined via a solder ball; and under-filling resin with which is filled up between the semiconductor package and the wiring substrate, wherein the under-filling resin is filled up with so that at least a part of exposed part of the porosity elastomer remains exposed.

A semiconductor device concerning claim 5 of the present invention comprises a semiconductor package which has a semiconductor chip and mold resin exposed to a ball surface side, a wiring substrate over which the semiconductor package was joined via a solder ball, and under-filling resin with which a gap between the semiconductor package and the wiring substrate is filled up, wherein the under-filling resin does not touch the mold resin exposed to the ball surface side.

A semiconductor device concerning claim 8 of the present invention comprises a wiring substrate, a first semiconductor element mounted over the wiring substrate, a second semiconductor element that is mounted over the wiring substrate and whose height is lower than the first semiconductor element, a metal plate formed over the second semiconductor element so that an upper surface might become the same height as an upper surface of the first semiconductor element, and a case adhered to an upper surface of the first semiconductor element, and an upper surface of the metal plate. The other features of the present invention are made clear to below.

The semiconductor device concerning claim 1 of the present invention can protect destruction of a low dielectric constant film and a bump's destruction which consists of lead free solder both.

The semiconductor device concerning claim 3 of the present invention can prevent emission of the steam through the elastomer from being hampered by under-filling resin.

The semiconductor device concerning claim 5 of the present invention can prevent peeling of the interface of the mold resin exposed to the ball surface side of a semiconductor package and under-filling resin from spreading, and destruction of internal wiring and the short-circuit of solder balls from occurring.

With the semiconductor device concerning claim 8 of the present invention, even when the semiconductor elements having different heights are mounted on a wiring substrate, the heat radiation property from each semiconductor element to a case can be secured.

### BRIEF DESCRIPTION OF THE DRAWINGS

FIG. 1 is a flow chart which shows the manufacturing method of the semiconductor device concerning Embodiment 1 of the present invention;

FIG. 2 is a cross-sectional view showing the manufacturing process of a semiconductor package;

FIG. 3 is an enlarged sectional view showing a part of semiconductor chip;

FIG. 4 is a side view showing the manufacturing process of a semiconductor package;

FIGS. 5 to 7 are enlarged sectional views showing near the interface of mold resin and a metallic mold;

FIGS. 8 to 16 are side views showing the manufacturing process of the semiconductor device concerning Embodiment 1 of the present invention;

FIG. 17 is an enlarged side view showing the manufacturing process of the semiconductor device concerning Embodiment 1 of the present invention;

FIG. 18 is a drawing showing the temperature characteristics of the coefficient of thermal expansion of under-filling resin concerning Embodiment 1 of the present invention;

FIG. 19 is a drawing showing the temperature characteristics of the elastic modulus of under-filling resin concerning Embodiment 1 of the present invention;

FIG. 20 is a drawing which examined the existence of Low-k destruction and a bump crack for the case where four kinds of under-filling resin are used;

FIGS. 21 and 22 are side views showing the manufacturing process of the semiconductor device concerning Embodiment 1 of the present invention;

FIGS. 23 and 24 are side views showing the manufacturing process of the semiconductor device concerning Embodiment 2 of the present invention; and

FIG. 25 is a top view showing the manufacturing process of the semiconductor device concerning Embodiment 3 of the present invention.

### DETAILED DESCRIPTION OF THE PREFERRED EMBODIMENTS

### Embodiment 1

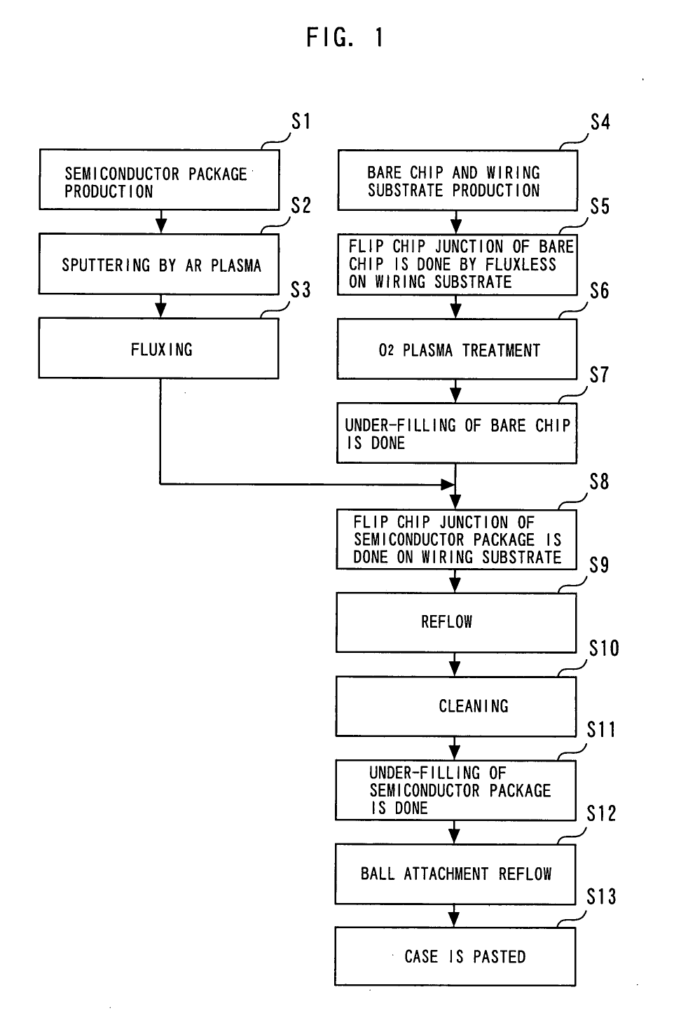

It explains referring to the flow chart of FIG. 1 for the manufacturing method of the semiconductor device concerning Embodiment 1 of the present invention hereafter.

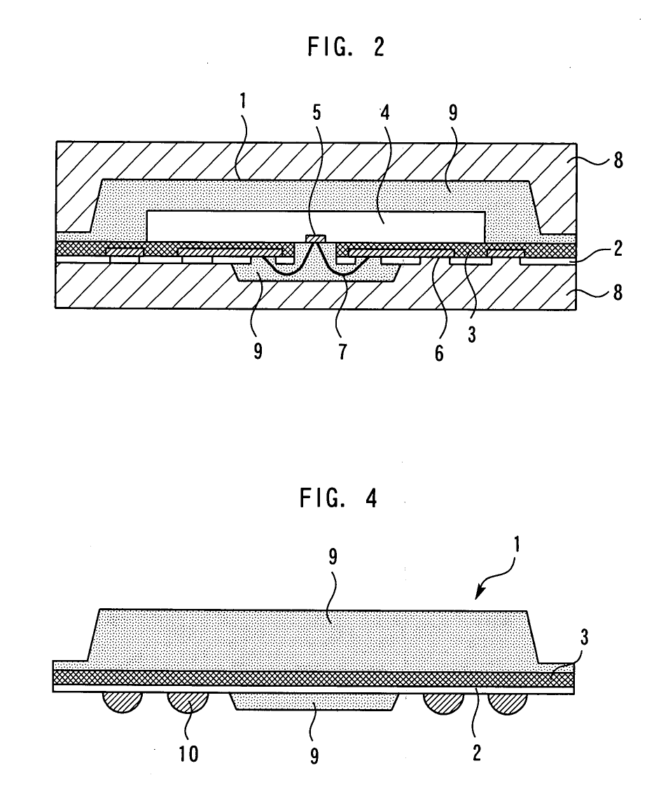

First, semiconductor package 1 is produced (Step S1). Concretely, as shown in FIG. 2, semiconductor chip 4 is mounted via porosity elastomer 3 on substrate 2. And center pad 5 of semiconductor chip 4 and electrode 6 of substrate 2 are connected with wire 7 passing through the opening of substrate 2 center. Metallic mold 8 is equipped with substrate 2, and batch sealing of semiconductor chip 4, wire 7, and the porosity elastomer 3 is done with mold resin 9. However, porosity elastomer 3 to which semiconductor chip 4 was attached is exposed from a package side surface.

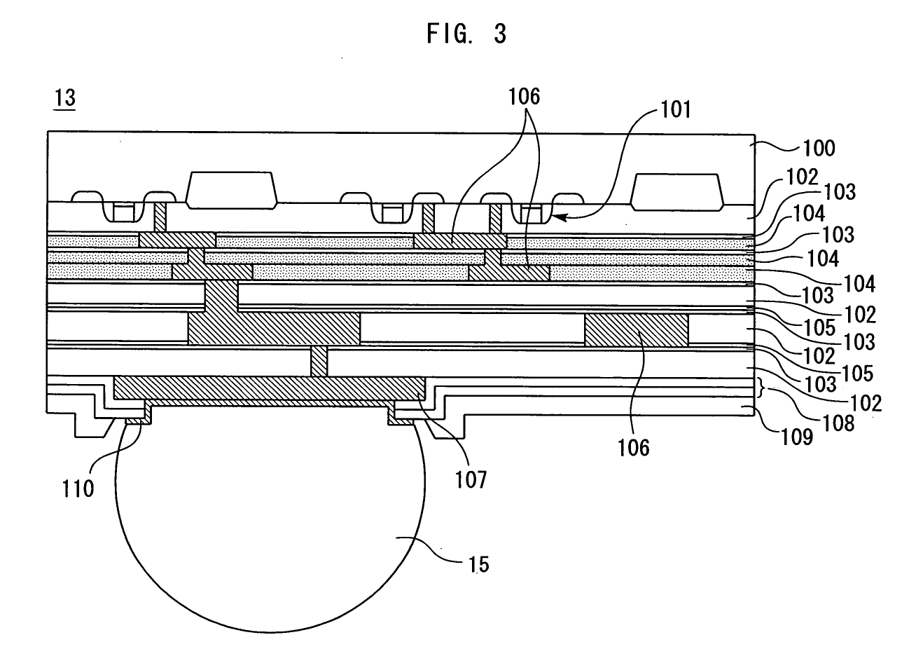

FIG. 3 is an enlarged sectional view showing a part of semiconductor chips 13 for flip chip connection mentioned later. Semiconductor chip 13 is provided with silicon substrate 100, semiconductor elements 101 formed on silicon substrate 100, such as MOSFET, the interlayer insulation film which consists of a laminated structure of SiO₂ insulating film 102, SiCN etching stopper film 103, porous SiOC film 104 which is a low dielectric constant film, and SiOF tightly adhering film 105, wiring layer 106 in a semiconductor chip which consists of a tungsten plug embedded at this interlayer insulation film, Cu wiring, etc., aluminum pad layer 107 formed on the interlayer insulation film, the laminated film of inorganic matter passivation film 108 with which the opening was formed so that aluminum pad 107 might be exposed and which consists of a SiO₂/SiN laminated film, and organic passivation film 109 which consists of a polyimide film (PiQ film), barrier metal 110 which was formed on aluminum pad 107 and which for example, consists of a Ti/Cu/nickel laminated film, and solder bump 15 formed on the barrier metal. As an interlayer insulation film in semiconductor chip 13, when using the film of a dielectric constant lower than dielectric constant K=4.3 of SiO₂ film, the strength reduction of an interlayer insulation film poses a problem. Especially, as compared with the TEOS film which is SiO₂ common film, the problem is remarkable in the porous low dielectric constant film which reduces a dielectric constant by reducing the density of a film. The technology of reducing the stress applied to a semiconductor chip becomes very important, when improving the reliability of a semiconductor device. In this embodiment, a porous SiOC film is adopted as a low dielectric constant film. This porous SiOC film is methyl-containing polysiloxane which mainly includes many S₁-CH₃ groups, a gap is generated in molecular structure by existence of CH₃, it becomes porosity, and the dielectric constant is falling. Although the example was shown above as a material which forms semiconductor chip 13, it does not restrict to these. For example, as a low dielectric constant film, the porous low dielectric constant film of a SiOCH base, porous silica system materials, such as a Nano Clustering Silica film, the H-containing polysiloxane called porous HSQ, an organic polymer film, the porous film of organic polymer, etc. are available suitably.

After the resin seal step shown in FIG. 2, as shown in FIG. 4, bump 10 which consists of lead free solder is attached on the under surface of substrate 2. Hereby, semiconductor package 1 whose mold resin 9 exposed to the ball surface side is produced. Here, lead free solder is solder in which lead is not included or only lead of the grade (less than 0.1 wt %) with few environmental impacts is included. Here, what Cu contained 1 to 4% in Sn is used as lead free solder. However, the thing of a Sn—Bi system, a Sn—Ag system, or pure Sn etc. may be used as lead free solder.

Thus, when forming mold resin 9 with metallic mold 8, mold resin 9 with which the release agent was included is used. As a release agent, wax or fatty acid, such as natural wax, such as paraffin wax, rice wax, carnauba wax, and candelilla wax, oil system wax, such as polyethylene wax and oxidized polyethylene wax, high-class aliphatic series ketone, high-class aliphatic series ester, higher fatty acid, high-class fatty alcohol, etc. is mentioned. In order to reduce a warp of semiconductor package 1, a lot of fillers are added to mold resin 9. That is, semiconductor substrates, such as a single crystal silicon substrate used as the main structures of semiconductor chip 4, have a small coefficient of thermal expansion. Therefore, the coefficient of thermal expansion as the semiconductor chip 4 whole also becomes very small with 3 ppm/° C. grade. Generally not only a single crystal silicon substrate but an SOI (Silicon On Insulator) substrate has a small coefficient of thermal expansion too compared with epoxy system resin etc. So, the filler which consists of silica with a coefficient of thermal expansion small to epoxy system resin etc. is added to mold resin 9 in large quantities, and the material which made thermal expansion coefficient difference with semiconductor chip 4 as small as possible is used for it. In this embodiment, the material in which silica of more than 80 wt % at least, more preferably about 90 wt % to epoxy system resin is added is used as mold resin 9. In such a case, the filler which consists of silica etc. has a high elastic modulus as compared with the epoxy system resin which forms mold resin 9, for example, and the internal stress generated to semiconductor chip 4 sealed by mold resin 9 inside becomes quite high. So, a little flexibilizer may be added to mold resin 9 as a low stress agent. As flexibilizer, various silicone oil, silicone rubber, acrylic nitrile butadiene rubber, etc. may be used. In particular, various silicone oil, such as epoxy modified silicone oil, is effective from sides, such as chemical stability. However, when using mold resin 9 with which silicone oil was added, guarantee of adhesive strength with under-filling resin 20 becomes difficult. There is character in which it is difficult to secure adhesive power and adhesive strength with other organic substances etc. in silicone oil as it may be used for a release agent. In mold resin 9 which contains the silica filler beyond 80 wt % at least, in order to attain stress reduction and to prevent the crack of semiconductor chip 4, it is preferred to add the silicone oil beyond 0.3 wt %. However, when the content of silicone oil exceeds 0.1 wt %, it will become difficult to secure adhesive strength with other organic resin.

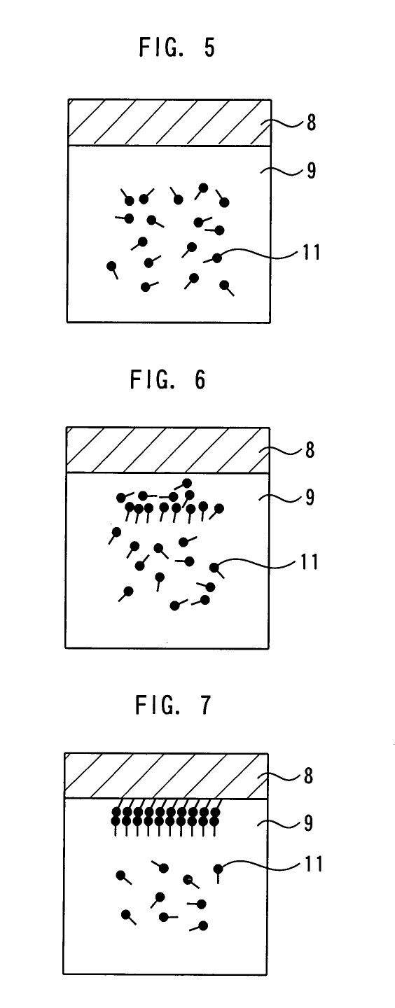

As shown in FIG. 5 immediately after formation, release agent 11 is distributed in mold resin 9. However, when time passes, as shown in FIG. 6, release agents 11 will begin to gather in mold resin 9. And eventually, as shown in FIG. 7, the layer of release agent 11 is formed near an interface with metallic mold 8. The layer of this release agent 11 becomes the cause of degrading the adhesive property of mold resin 9 and under-filling resin (after-mentioned).

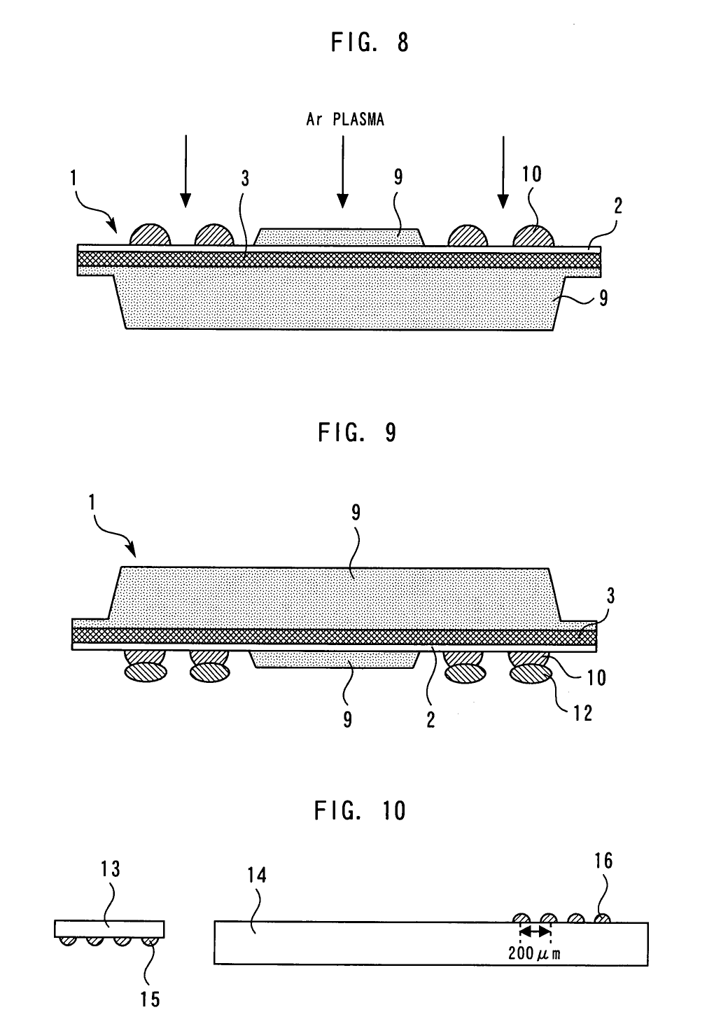

Then, as shown in FIG. 8, sputtering of the ball surface of semiconductor package 1 is done by Ar plasma (Step S2). That is, Ar plasma is accelerated in an electric field and it hits against the ball surface of semiconductor package 1. Hereby, the layer of release agent 11 formed in the front surface of mold resin 9 is physically removable with plasma. The front surface of mold resin 9 can be made rough, and a contact area with under-filling resin (after-mentioned) can also be increased. The surface treatment according to Ar plasma is effective also when securing the adhesive strength of mold resin 9 containing silicone oil and under-filling resin 20. As a means to reform a resin front surface and to improve adhesive property with a binder, there was a means of Ar plasma and oxygen plasma cleaning. To mold resin 9 in this embodiment, there is the feature that the effect of an improvement of adhesive strength is not fully acquired in oxygen plasma cleaning, but the improving effect of adhesive strength is fully acquired with Ar plasma. When oxygen plasma cleaning is performed for example, to wiring substrate 14 front surface, an organic combination will be cut by oxygen radical plasma, a functional group having included oxygen will be formed in a front surface, and the active surface state which was extremely rich in adhesive property will be acquired. However, the silicone oil contained in mold resin 9, for example, the silicone oil which did epoxy modification in part, is dramatically excellent in the stability over thermal oxidation. Therefore, there is a problem that progress of cutting of a methyl group is slow and formation of the functional group which is rich in adhesive property does not fully progress even if it exposes to oxygen radical plasma for a long time. It is accelerating by a big electric field, and Ar ion in Ar plasma is made to collide with mold resin 9 used as a target in processing by Ar plasma. When Ar ion with high energy collides, the methyl group of silicone oil is cut effectively. And in a subsequent under-filling resin injection step (after-mentioned), since a firm combination is formed between side chain of polysiloxane, and under-filling resin 20, improvement in adhesive strength with under-filling resin 20 is obtained.

However, in a sputtering step, it is preferred that the amount of shaving of mold resin 9 is made below the average of the diameter of the filler included in mold resin 9. It can prevent a filler dropping out of mold resin in large quantities by this, and the defect of ball connection can be prevented.

Next, flux 12 is applied to the ball surface of semiconductor package 1 as shown in FIG. 9 (Step S3).

Next, as shown in FIG. 10, bare chip 13 and wiring substrate 14 are produced (Step S4). Solder ball 15 which consists of lead free solder is attached to bare chip 13, and solder ball 16 which consists of lead free solder is attached to wiring substrate 14. A plurality of these solder balls 15 and 16 are put in order at intervals of 200 μm, respectively.

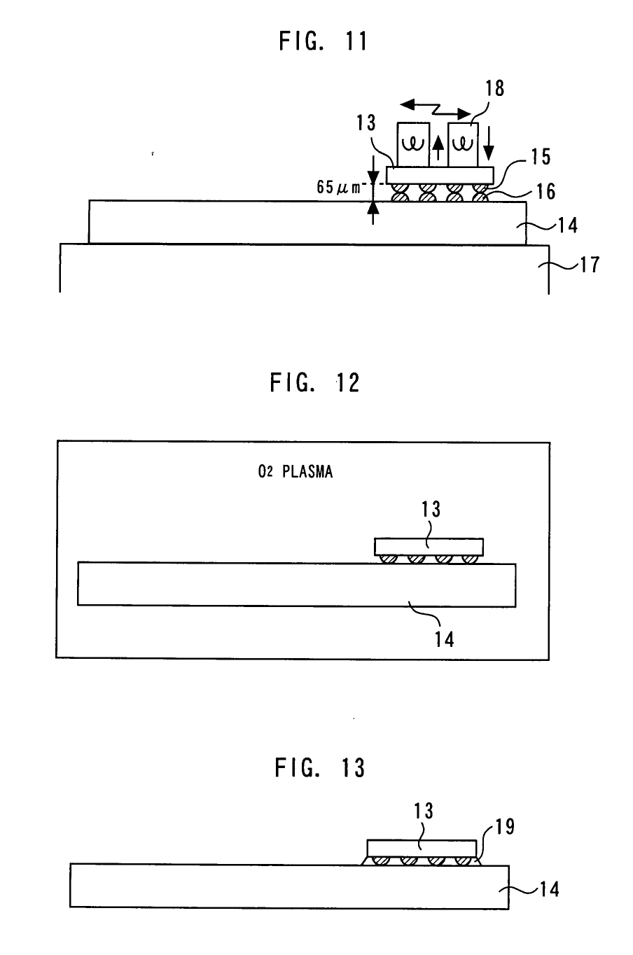

Next, as shown in FIG. 11, wiring substrate 14 is mounted on stage 17, bare chip 13 is held with tool 18, and tool 18 and stage 17 are heated to 180° C. And tool 18 is heated to 300° C. which is high temperature rather than the melting point (in Sn1% Ag0.5% Cu, it is 210° C.) of solder, contacting solder ball 15 and solder ball 16, and maintaining stage 17 at 180° C. Flip chip junction of the bare chip 13 is done by a fluxless on wiring substrate 14, applying supersonic vibration to bare chip 13 (Step S5). Here, the amplitude of supersonic vibration is made into the ±35 μm grade which is about ⅓ of diameter 100 μm of solder balls 15 and 16, and applying time is made into about 1 second. Then, maintaining stage 17 at 180° C., tool 18 is cooled to 200° C. and tool 18 is raised.

Thus, by applying supersonic vibration, the natural-oxidation film of solder ball 15 and 16 front surface can be destroyed in a fluxless, and good junction can be realized. Since the gap of bare chip 13 and wiring substrate 14 is as narrow as 65 μm grade when flux is used, the flux between both cannot be flushed but a flux residue occurs. On the other hand, there are no worries about the generation of a flux residue by joining by a fluxless. Therefore, the generation of the void by flux expanding within under-filling resin can be prevented.

Next, as shown in FIG. 12, O₂ plasma treatment is performed to bare chip 13 (Step S6). In O₂ plasma treatment, wiring substrate 14 to which bare chip 13 was connected is exposed in oxygen radical plasma with a direct plasma method. An organic combination of the solder-resist film of wiring substrate 14 front surface and the polyimide passivation film of bare chip 13 front surface is cut by it as above-mentioned. Since a functional group having included oxygen is formed in a front surface, the active surface state which was extremely rich in adhesive property is acquired. In particular, in a direct plasma method, cleaning of a narrow place can also be performed as compared with the method which accelerates and makes Ar ion collide in an electric field. Therefore, the cleaning after doing flip chip junction of the bare chip 13 at wiring substrate 14 is also possible.

Here, since only two element systems can be formed in plating, solder ball 15 of bare chip 13 consists of Sn2.5% Ag, and solder ball 16 of wiring substrate 14 consists of SnCu. And when both solder balls 15 and 16 join by flip chip junction, reliable Sn1% Ag0.5% Cu will be formed. However, since only solder ball 15 of bare chip 13 can be shaved and the composition ratio of the solder formed of junction will change when sputtering of the ball surface of bare chip 13 is done with Ar plasma, there is a problem that reliability is spoiled. When sputtering is done with Ar plasma, there is also a problem that the trap of the electric charge will be done by the charge up to the gate insulating film in bare chip 13, and an element characteristic will change. Therefore, it is better not to do sputtering of the bare chip 13 by Ar plasma.

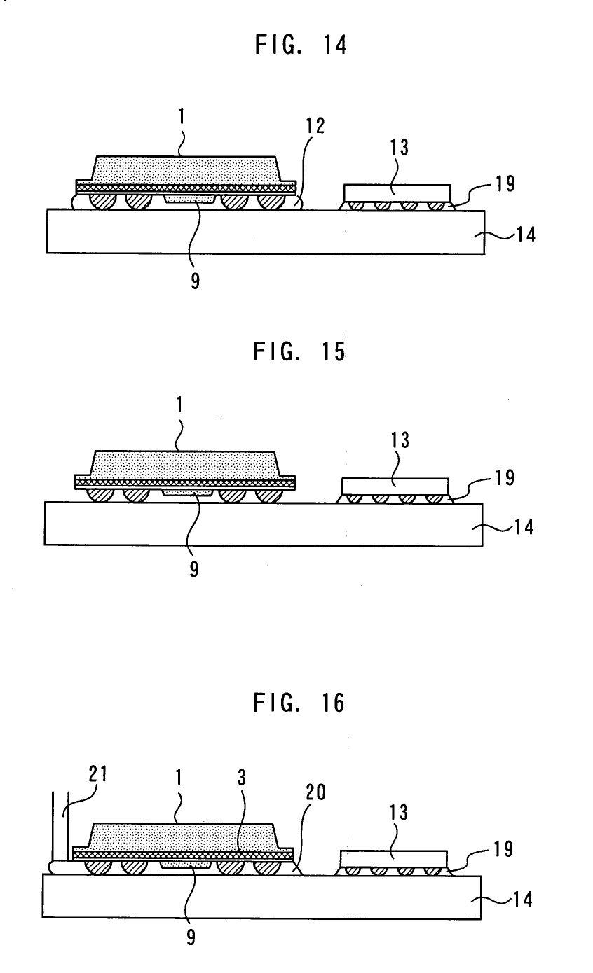

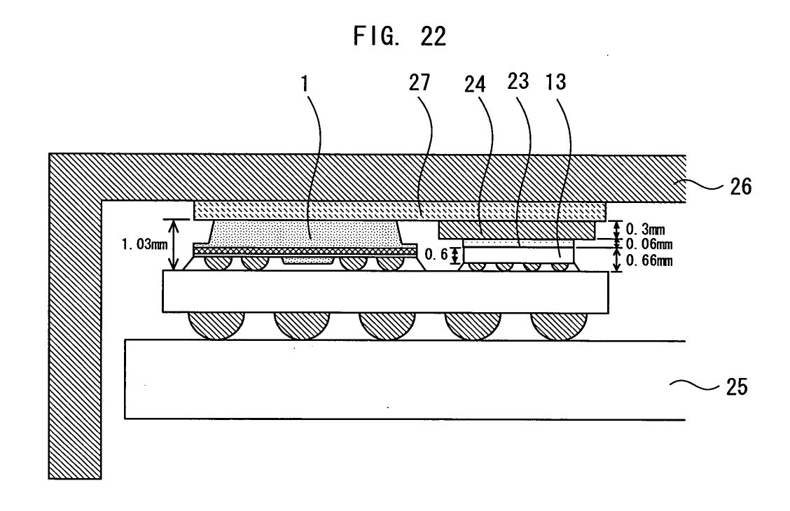

Next, as shown in FIG. 13, it is filled up with under-filling resin 19 between bare chip 13 and wiring substrate 14 (Step S7). Then, under-filling resin 19 is hardened by performing heat treatment for 160° C. and 90 minutes, for example. By the time it completes as a semiconductor device, the further heat treatment processes, such as a reflow step of solder ball 22 shown in FIG. 21 and an assembling step to wiring substrate 14 shown in FIG. 22, may be given, for example. Also in these later heat treatment processes, the hardening reaction of under-filling resin 19 progresses suitably, and resin of desired characteristics is obtained. Thus, by performing under-filling resin about bare chip 13, before mounting semiconductor package 1, it can prevent flux 12 of semiconductor package 1 entering between bare chip 13 and wiring substrate 14 in a later step.

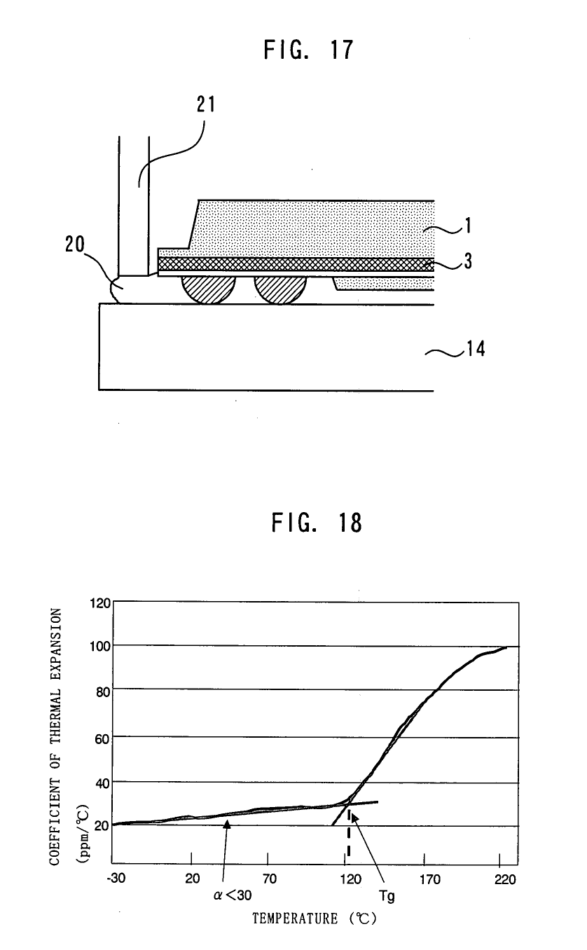

Next, as shown in FIG. 14, flip chip junction of the semiconductor package 1 is done on wiring substrate 14 (Step S8). And reflow (melting) is performed in a nitrogen atmosphere (Step S9). Then, as shown in FIG. 15, it cleans and flux 12 is removed (Step S10). On this occasion, it is preferred to use the cleaning agent of an organic solvent system, such as alcohol, in the case of rosin system flux, and to use pure water etc. in the case of water-soluble flux.

Next, as shown in FIG. 16, under-filling resin 20 is poured in between semiconductor package 1 and wiring substrate 14 (Step S11). However, as shown in FIG. 17, nozzle 21 for pouring in under-filling resin 20 is lowered rather than the exposed part of porosity elastomer 3. Pouring in under-filling resin 20 moving nozzle 21 along the side of semiconductor package 1, it leaves at least a part of exposed part of porosity elastomer 3. Hereby, the steam generated inside the package at the time of latter reflow is emitted through porosity elastomer 3.

Here, when using epoxy system resin and bismaleide triazine system resin as a base material and under-filling resin 19 exceeds glass transition temperature Tg, a coefficient of thermal expansion will become very large with more than 90 ppm/° C. Then, resin whose glass transition temperature Tg is more than 125° C. is used as under-filling resin 19. In this embodiment, glass transition temperature Tg is defined as a value calculated by the TMA method. Concretely, temperature up of under-filling resin 19, or the test piece of the same material is done at a ratio of 10° C./min, and the thermal expansion amount of a thickness direction is measured with a thermal analysis apparatus. As shown in FIG. 18, the graph whose horizontal axis is temperature and whose vertical axis is a coefficient of thermal expansion is drawn. A broken line is drawn on the curve before and behind glass transition temperature, and it defines as a temperature searched for from the intersection of this tangent. By increasing the amount of the curing agent added to under-filling resin 19, glass transition temperature Tg of under-filling resin can be made high. As a curing agent, when under-filling resin 19 uses epoxy system resin as a base material, an imidazole compound etc. can be chosen, for example. Hereby, the volume change of under-filling resin 19 in the operation-ensuring-temperature range (−55° C.˜125° C.) can be suppressed. As a measurement condition of under-filling resin 19, it is preferred that the physical properties in the state where the history of heat treatment at the high temperature received a process until a semiconductor device is mounted on a mounting substrate was received are desired values not immediately after filling up with and hardening under-filling resin 19 between bare chip 13 and wiring substrate 14. For example, as an example of the heat history after an under-filling pouring step, there are a reflow step of solder ball 22 shown in the below-mentioned FIG. 21, a heat treatment process which is shown in FIG. 22 and which does melting of the solder ball 22 and mounts it to up to a mounting substrate, etc.

As under-filling resin 19, the side where the difference of a coefficient of thermal expansion with solder bump electrodes 15 and 16 is as small as possible is preferred. As for under-filling resin 19, when glass transition temperature is exceeded, a coefficient of thermal expansion will become large suddenly. Therefore, in order to prevent an extreme change of the coefficient of thermal expansion in operation-ensuring-temperature within the limits, it is preferred to use resin whose glass transition temperature Tg is higher than 125° C. as under-filling resin 19, as shown in FIG. 18. Generally solder bumps' 15 and 16 coefficient of thermal expansion formed with lead free solder is 20 ppm/° C. grade. When thermal expansion coefficient difference with solder bumps 15 and 16 exceeds 20 ppm/° C., solder bump's 15,16 creep limit is exceeded, a possibility of resulting in fracture within solder bumps 15 and 16 will become large, and falling of the reliability of a semiconductor device will become remarkable. Therefore, it is preferred as under-filling resin 19 that the difference of the maximum value of a coefficient of thermal expansion of the operation-ensuring-temperature range, for example, −55° C.˜125° C., and the coefficient of thermal expansion of solder bumps 15 and 16 in the temperature becomes less than 20 ppm/° C. at the maximum. The difference of a coefficient of thermal expansion becomes large in many cases as it becomes high temperature, and when it takes into consideration that the coefficient of thermal expansion of lead free solder is generally 20 ppm/° C., it is preferred to use resin whose coefficient of thermal expansion in 125° C. is less than 40 ppm/° C. Hereby, cubical expansion at the time of high temperature can be made small. Therefore, when solder bump electrodes 15 and 16 which connect bare chip 13 and wiring substrate 14 consist of lead free solder with a low creep limit, destruction of these solder bump electrodes 15 and 16 can be prevented.

As under-filling resin 19, as shown in FIG. 19, resin whose elastic modulus in 25° C. is 7.7 GPa is used. Thus, by using resin whose elastic modulus in 25° C. is less than 9 GPa, the stress concentration to the corner part of semiconductor chip 13 at the time of low temperature etc. can be eased, and destruction of a low dielectric constant film can be prevented. However, it is in the tendency for the elastic modulus in low temperature to become high when Tg is made high. Then, the elastic modulus in low temperature can be made low, making Tg high by fully adding flexibilizer, such as powder which consists of silicone resin or silicone rubber.

As under-filling resin 19, as shown in FIG. 19, resin whose elastic modulus in 125° C. is 1.4 GPa, and whose minimum value of the elastic modulus at more than 125° C. is 0.18 GPa is used. Thus, resin whose elastic modulus in 125° C. is at least 0.1 or more GPa, more desirably, 1.0 or more GPa is used. Hereby, since it is hard to concentrate stress to a bump and it is hard to transform under-filling resin with internal stress at the time of high temperature, destruction of the bump which consists of lead free solder can be prevented still more surely.

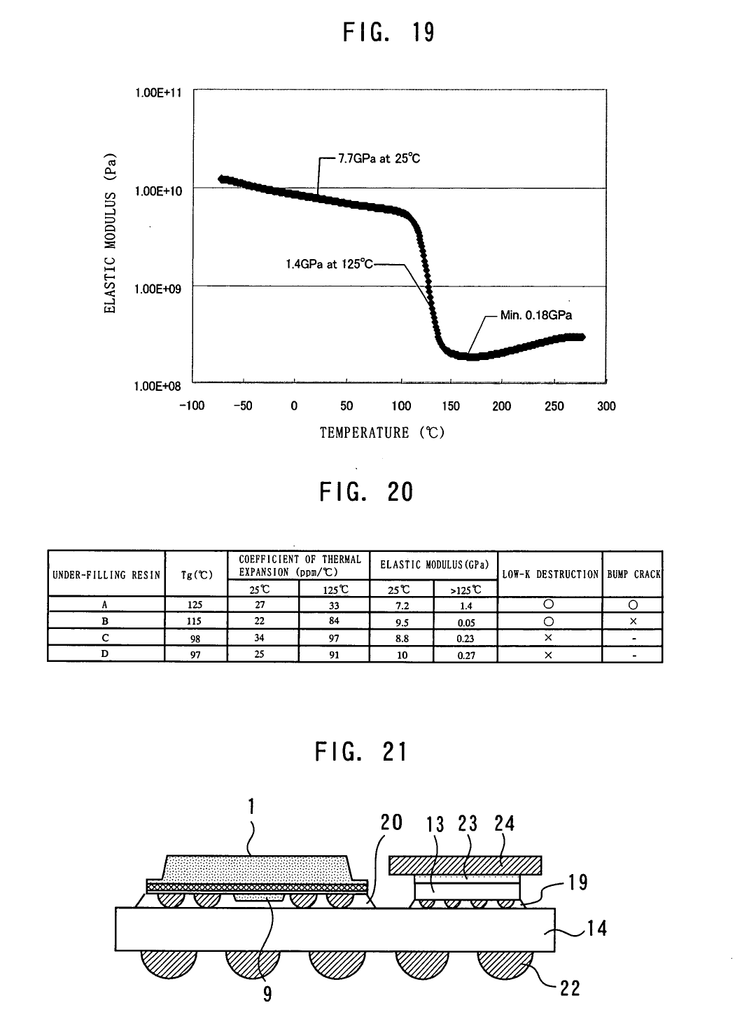

Here, FIG. 20 is the drawing which examined the existence of destruction (Low-k destruction) of a low dielectric constant film, and destruction (bump crack) of the bump which consists of lead free solder when four kinds of under-filling resin A-D from which glass-transition-temperature Tg, a coefficient of thermal expansion, and an elastic modulus differ are used. From this drawing, when using under-filling resin A which satisfies the above-mentioned conditions, it turns out that both of the destruction of a low dielectric constant film and a bump's destruction which consists of lead free solder can be prevented.

Next, as shown in FIG. 21, solder ball 22 is attached to the under surface of wiring substrate 14 for external connection, and reflow is performed (Step S12). In the reflow step of solder ball 22, solder ball 22 is melted by heat-treating beyond the melting point of solder ball 22 formed with lead free solder. For example, a reflow step is performed by performing heat treatment at 260° C. and 10 seconds or more. Although heat stress occurs by this reflow, since the adhesive property of mold resin 9 and under-filling resin 20 is improved as mentioned above, peeling by both interface can be prevented.

Although semiconductor package 1 (first semiconductor element) and bare chip 13 (second semiconductor element) are mounted on wiring substrate 14, bare chip 13 has height lower than semiconductor package 1. Then, metal plate 24 with which the upper surface becomes the same height as the upper surface of the first semiconductor element is formed via resin 23 on bare chip 13. However, metal plate 24 is made thicker than resin 23.

Then, as shown in FIG. 22, wiring substrate 14 is mounted on mounting substrate 25. In the step which mounts wiring substrate 14 on mounting substrate 25, solder ball 22 is melted and solidified and wiring substrate 14 and mounting substrate 25 are joined electrically and mechanically via solder ball 22. As heat treatment temperature of an assembling step, a temperature higher than the melting point of solder ball 22 is used. For example, heat treatment at 260° C. and 10 seconds or more is performed. And the upper surface of semiconductor package 1 and the upper surface of metal plate 24 are adhered on cases 26, of such as car navigation, via carbon sheet 27 (Step S13). Here, the height of semiconductor package 1 comprising a bump is 1.03 mm, the thickness of bare chip 13 itself is 0.6 mm, the height of bare chip 13 including a solder ball is 0.66 mm, the thickness of resin 23 is 0.06 mm, and the thickness of metal plate 24 is 0.3 mm.

Thus, it becomes easy to paste flat case 26 by forming metal plate 24 on bare chip 13, so that the upper surface may become the same height as the upper surface of semiconductor package 1, or so that the difference of height may become small enough. It is effective when pasting these up via hard carbon sheet 27 especially. A thick insulating member was not formed on each semiconductor element like before, but metal plate 24 whose thermal conductivity is higher than an insulating member is formed, and heat radiation property improves. By making thickness of metal plate 24 thicker than resin 23, the rise of the thermal resistance between semiconductor chip 13 and carbon sheet 27 can be prevented. Therefore, even when the semiconductor element from which height differs is mounted on wiring substrate 14 as mentioned above, the heat radiation property from each semiconductor element to a case can be secured.

### Embodiment 2

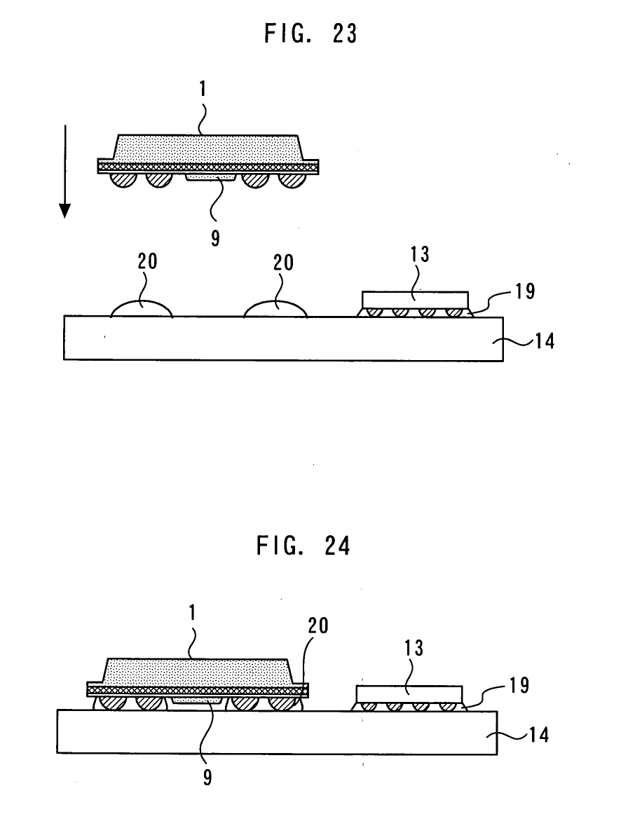

In Embodiment 2 of the present invention, the pouring method of under-filling resin 20 differs from Embodiment 1. First, as shown in FIG. 23, under-filling resin 20 is applied on wiring substrate 14. Next, flip chip junction of the semiconductor package 1 is done on wiring substrate 14 via under-filling resin 20 applied on wiring substrate 14. On this occasion, under-filling resin 20 is kept from touching mold resin 9 exposed to the ball surface side. Other structures are the same as that of Embodiment 1.

Hereby, it can prevent peeling of the interface of mold resin 9 exposed to the ball surface side of semiconductor package 1 and under-filling resin 20 spreading, and destruction of internal wiring and the short-circuit of solder balls occurring. This structure can be similarly applied, when potting resin is used instead of mold resin 9. When keeping under-filling resin 20 and mold resin 9 from touching, it is also possible to skip the sputtering step by Ar plasma of a description to FIG. 8 etc.

When pouring in under-filling resin 20, it leaves at least a part of exposed part of porosity elastomer 3. Hereby, the steam generated inside the package at the time of latter reflow is emitted through porosity elastomer 3.

### Embodiment 3

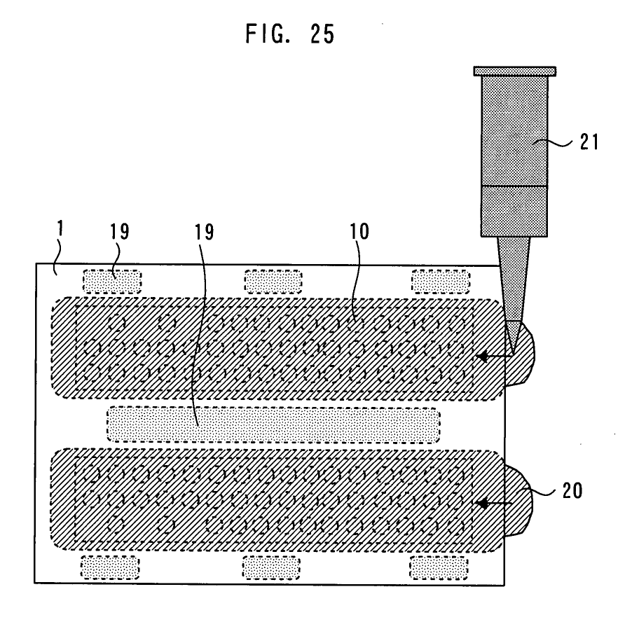

In Embodiment 3 of the present invention, the pouring method of under-filling resin 20 differs from Embodiment 1. As shown in FIG. 25, under-filling resin 20 is poured in between semiconductor package 1 and wiring substrate 14 only from one point or several points of the periphery of semiconductor package 1 by nozzle 21. On this occasion, under-filling resin 20 is kept from touching mold resin 9 exposed to the ball surface side. Other structures are the same as that of Embodiment 1.

Hereby, it can prevent peeling of the interface of mold resin 9 exposed to the ball surface side of semiconductor package 1 and under-filling resin 20 spreading, and destruction of internal wiring and the short-circuit of solder balls occurring. This structure can be similarly applied, when potting resin is used instead of mold resin 9. When keeping under-filling resin 20 and mold resin 9 from touching, it is also possible to skip the sputtering step by Ar plasma of a description to FIG. 8 etc.

When pouring in under-filling resin 20, it leaves at least a part of exposed part of porosity elastomer 3. Hereby, the steam generated inside the package at the time of latter reflow is emitted through porosity elastomer 3.

What is claimed is:

1. A semiconductor device, comprising:
a semiconductor package which has a semiconductor chip including a low dielectric constant film and a bump which includes lead free solder;
a wiring substrate over which flip chip junction of the semiconductor package was done via the bump; and
under-filling resin with which a gap between the semiconductor package and the wiring substrate is filled up;
wherein
as for the under-filling resin, glass transition temperature is equal to or more than 125° C., coefficient of thermal expansion in 125° C. is less than 40 ppm/° C., and elastic modulus in 25° C. is less than 9 GPa.

2. A semiconductor device according to claim 1, wherein
elastic modulus in 125° C. of the under-filling resin is 0.1 GPa or more.

3. A semiconductor device, comprising:
a semiconductor package which has a semiconductor chip and a porosity elastomer to which the semiconductor chip is attached and which is exposed from a package side surface;
a wiring substrate to which the semiconductor package is joined via a solder ball; and
under-filling resin with which between the semiconductor package and the wiring substrate is filled up;
wherein
the under-filling resin is filled up with so that at least a part of exposed part of the porosity elastomer remains exposed.

4. A method of manufacturing the semiconductor device according to claim 3, wherein
a nozzle for pouring in the under-filling resin is lowered rather than an exposed part of the porosity elastomer, and the under-filling resin is poured in between the semiconductor package and the wiring substrate.

5. A semiconductor device, comprising:
a semiconductor package which has a semiconductor chip and mold resin exposed to a ball surface side;
a wiring substrate over which the semiconductor package was joined via a solder ball; and
under-filling resin with which a gap between the semiconductor package and the wiring substrate is filled up;
wherein
the under-filling resin does not touch the mold resin exposed to the ball surface side.

6. A method of manufacturing the semiconductor device according to claim 3, comprising the steps of
applying under-filling resin over the wiring substrate; and
doing flip chip junction of the semiconductor package over the wiring substrate via the under-filling resin applied over the wiring substrate.

7. A method of manufacturing the semiconductor device according to claim 3, wherein
only from one point or several points of a periphery of the semiconductor package, the under-filling resin is poured in between the semiconductor package and the wiring substrate.

8. A semiconductor device, comprising:
a wiring substrate;
a first semiconductor element mounted over the wiring substrate;
a second semiconductor element that is mounted over the wiring substrate and whose height is lower than the first semiconductor element;
a metal plate formed over the second semiconductor element so that an upper surface might become the same height as an upper surface of the first semiconductor element; and
a case adhered to an upper surface of the first semiconductor element, and an upper surface of the metal plate.

9. A semiconductor device, comprising:
a semiconductor package which has a semiconductor chip including a low dielectric constant film and a bump which includes lead free solder;
a wiring substrate over which flip chip junction of the semiconductor package is done via the bump; and
under-filling resin with which a gap between the semiconductor package and the wiring substrate is filled up;
wherein
the under-filling resin is 0.1 GPa or more in elastic modulus in 125° C., and is less than 9 GPa in elastic modulus in 25° C.

10. A semiconductor device according to claim 9, wherein
glass transition temperature of the under-filling resin is more than or equal to 125° C.
